(19) United States
(12) Patent Application Publication
(10) Pub. No.: US 2020/0350477 A1
(43) Pub. Date: Nov. 5, 2020

(54) LIGHT EMITTING DIODE ELEMENT, METHOD OF MANUFACTURING LIGHT EMITTING DIODE ELEMENT, AND DISPLAY PANEL INCLUDING LIGHT EMITTING DIODE ELEMENT

(71) Applicant: SAMSUNG ELECTRONICS CO., LTD., Suwon-si (KR)

(72) Inventors: Jaephil SHIM, Suwon-si (KR); Jihoon KANG, Suwon-si (KR); Myunghee KIM, Suwon-si (KR); Jenghun SUH, Suwon-si (KR); Jitsuo OTA, Suwon-si (KR)

(73) Assignee: SAMSUNG ELECTRONICS CO., LTD., Suwon-si (KR)

(21) Appl. No.: 16/864,564

(22) Filed: May 1, 2020

(30) Foreign Application Priority Data
May 2, 2019 (KR) 10-2019-0051670

(51) Int. Cl. H01L 33/62; H01L 33/50; H01L 33/60; G09G 3/32; H01L 33/00; H01L 25/075

(52) U.S. Cl. CPC H01L 33/62; H01L 33/502; H01L 33/60; H01L 2933/0066; H01L 33/005; H01L 25/0753; H01L 2933/0016; G09G 3/32

(57) ABSTRACT

A display panel including a plurality of LED elements and a driving circuit configured to drive the plurality of LED elements. The plurality of LED elements includes an LED element having a first light emitting cell including a first light emitting layer, a tunnel junction layer formed on the first light emitting layer, and a second light emitting cell formed on the tunnel junction layer and including a second light emitting layer. A first electrode is electrically connected to the first light emitting cell, and a second electrode is electrically connected to the second light emitting cell. The first light emitting cell is electrically connected to the second light emitting cell through the tunnel junction layer. The LED element is a flip-chip type LED element.

### CROSS-REFERENCE TO RELATED APPLICATION(S)

This application is based on and claims priority under 35 U.S.C. § 119 to Korean Patent Application No. 10-2019-0051670, filed on May 2, 2019, in the Korean Intellectual Property Office, the disclosure of which is incorporated by reference herein in its entirety.

### BACKGROUND

### Field

The disclosure relates to a light emitting diode (LED) element, a method of manufacturing an LED element, and a display panel including an LED element, and more particularly, to a high efficiency LED element capable of decreasing a driving current and consumed power of a display device, a method of manufacturing a high efficiency LED element, and a display device including a high efficiency LED element.

### Description of the Related Art

In recent years, a semiconductor-based light emitting diode (LED) element has been put to practical use in various industrial fields such as the display field due to high luminous efficiency and a long lifespan. A micro LED (mLED or pLED) display panel is one type of a flat panel display panel, and may include a plurality of inorganic LEDs each having a size of 100 micrometers or less. The micro LED display panel provides superior contrast, response time, and energy efficiency when compared to a liquid crystal display (LCD) panel requiring a backlight unit. Both of the organic LED (OLED) and the micro LED are energy efficient, but the micro LED has a higher brightness and luminous efficiency, as well as a longer lifespan of the OLED.

Micro LED elements have recently become prominent as light sources for forming individual pixel elements in a display device. To provide a valuable application of the micro LED, luminous efficiency of the micro LED element must be increased and power consumption of the display device must be decreased.

Additionally, a red micro LED element has lower luminous efficiency in a low current state than that of green and blue micro LED elements. Therefore, to satisfy high brightness characteristics of a display device including the micro LED elements, a high driving current needs to be allowed to flow to the red LEDs. As a result, problems such as an increase in power consumption and heat generation of the display device are produced.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter

Additional aspects will be set forth in part in the description which follows and, in part, will be apparent from the description, or may be learned by practice of the presented embodiments.

The disclosure provides a high efficiency light emitting diode (LED) element capable of decreasing a driving current and consumed power of a display device, a method of manufacturing an LED element, and a display device including an LED element.

According to an embodiment of the disclosure an LED element may include a first light emitting cell comprising a first light emitting layer, a tunnel junction layer formed on the first light emitting cell, a second light emitting cell formed on the tunnel junction layer and comprising a second light emitting layer, a first electrode electrically connected to the first light emitting cell, and a second electrode electrically connected to the second light emitting cell. The first light emitting cell may be electrically connected to the second light emitting cell through the tunnel junction layer, and the LED element may be a flip-chip type LED element in which the first electrode and the second electrode are arranged toward a surface of the LED element opposite to a light emitting surface of the LED element.

The first light emitting layer and the second light emitting layer may have matching band gap characteristics, and the matching band gap characteristics of the first light emitting layer and the second light emitting layer may correspond to a wavelength of red light.

According to another embodiment of the disclosure, a display panel may include a plurality of LED elements and a driving circuit configured to drive the plurality of LED elements. The plurality of LED elements may include a first LED element including a first light emitting cell comprising a first light emitting layer, a first tunnel junction layer formed above the first light emitting cell, a second light emitting cell formed on the first tunnel junction layer and comprising a second light emitting layer, a first electrode electrically connected to the first light emitting cell, and a second electrode electrically connected to the second light emitting cell.

The first light emitting cell may be electrically connected to the second light emitting cell through the first tunnel junction layer, and the first LED element may be a flip-chip type LED element in which the first electrode and the second electrode are arranged toward a surface of the first LED element opposite to a light emitting surface of the first LED element.

The first light emitting layer and the second light emitting layer may have matching band gap characteristics that may correspond to a wavelength of red light.

The first light emitting cell may include the first light emitting layer, a first n-type semiconductor layer formed above or beneath the first light emitting layer, and a first p-type semiconductor layer formed on a surface of the first light emitting layer opposite to a surface of the first light emitting layer on which the first n-type semiconductor layer is formed.

The second light emitting cell may include the second light emitting layer, a second n-type semiconductor layer formed above or beneath the second light emitting layer, and a second p-type semiconductor layer formed on a surface of the second light emitting layer opposite to a surface of the second light emitting layer on which the second n-type semiconductor layer is formed.

One of the first n-type semiconductor layer or the first p-type semiconductor layer that is formed above the first light emitting layer, the second light emitting layer, the second n-type semiconductor layer, and the second p-type semiconductor layer may transmit light emitted by the first light emitting layer and the second light emitting layer.

The first LED element may further include a contact hole extending through the first light emitting cell, the first tunnel junction layer, and a part of the second light emitting cell, and an insulating layer formed on a surface of the contact hole.

The second electrode may be electrically connected to the second light emitting cell through the contact hole.

The first LED element may further include a reflective layer formed to reflect light emitted from the first light emitting layer and the second light emitting layer toward the light emitting surface of the first LED element.

The first LED element may further include a third light emitting cell formed between the first light emitting cell and the first tunnel junction layer, the third light emitting cell may include a third light emitting layer; and a second tunnel junction layer formed between the first light emitting cell and the third light emitting cell.

The plurality of LED elements may further include a second LED element, and the second LED element may include a single light emitting layer.

The display panel may further include a plurality of pixels arranged in a matrix form, wherein each of the plurality of pixels comprises a R sub-pixel, a G sub-pixel, and a B sub-pixel.

In an embodiment, at least one of the R sub-pixel, the G sub-pixel, or the B sub-pixel may correspond to the first LED element.

In another embodiment, the R sub-pixel may correspond to the first LED element, and each of the G sub-pixel and the B sub-pixel may correspond to the second LED element.

In yet another embodiment, each of the R sub-pixel, the G sub-pixel, and the B sub-pixel may correspond to the first LED element.

The light emitting surface of the first LED element and a light emitting surface of the second LED element may be formed to have a corresponding height.

Each of the plurality of LED elements may be a micro LED element.

Accordingly to an embodiment of the disclosure, a method of manufacturing an LED element may include sequentially stacking a first n-type semiconductor layer, a first light emitting layer, and a first p-type semiconductor layer; stacking a tunnel junction layer on a surface of the first p-type semiconductor layer opposite the first light emitting layer; sequentially stacking a second n-type semiconductor layer, a second light emitting layer, and a second p-type semiconductor layer on a surface of the tunnel junction layer opposite the first p-type semiconductor layer; and forming a first electrode and a second electrode at a location removed from a light emitting surface of the LED element, the first electrode and the second electrode being electrically connected to the first n-type semiconductor layer and the second p-type semiconductor layer, respectively.

The first light emitting layer and the second light emitting layer may have band gap characteristics corresponding to a wavelength of red light.

An embodiment of the method may further include forming a contact hole through the first n-type semiconductor layer, the first light emitting layer, the first p-type semiconductor layer, the tunnel junction layer, the second n-type semiconductor layer, the second light emitting layer, and a part of the second p-type semiconductor layer; and forming an insulating layer on a surface of the contact hole.

The second electrode is electrically connected to the second p-type semiconductor layer through the contact hole.

### BRIEF DESCRIPTION OF THE DRAWINGS

The above and other aspects and features of certain embodiments of the present disclosure will be more apparent from the following description taken in conjunction with the accompanying drawings, in which:

FIG. 1A is a cross-sectional view illustrating a structure of a light emitting diode (LED) element according to a embodiments;

FIG. 1B is a cross-sectional view illustrating a structure of a light emitting diode (LED) element according to another embodiment;

FIG. 2 is a flow chart illustrating a method of manufacturing an LED element according to an embodiment;

FIGS. 3A to 3E are cross-sectional views illustrating an embodiment of an LED element at each operation of the method of manufacturing an LED element according to an embodiment;

FIGS. 4A to 4C are cross-sectional views illustrating another embodiment of an LED element at each operation of the method of manufacturing an LED element according to an embodiment;

FIG. 5 is a cross-sectional view illustrating a structure of an LED element including three light emitting cells according to an embodiment;

FIG. 6 is a block diagram illustrating a schematic configuration of a display device according to an embodiment;

FIG. 7 is a cross-sectional view illustrating a structure of a display panel according to an embodiment;

FIG. 8 is a view illustrating a pixel configuration of the display panel according to an embodiment;

FIGS. 9A and 9B are views illustrating a pixel configuration of the display panel together with LED elements corresponding to respective sub-pixels according to an embodiment;

FIG. 10 is a view illustrating an LED element according to the related art; and

FIG. 11A is a graph comparing the external quantum efficiency (EQE) versus current of an embodiment of an LED element of the present disclosure and an LED element of the related art;

FIG. 11B is a graph comparing the light intensity versus current of an embodiment of an LED element of the present disclosure and an LED element of the related art;

FIG. 11C is an enlarged portion of the graph of FIG. 11B based on box 1150.

Throughout the drawings and the detailed description, unless otherwise described, the same drawing reference numerals may refer to the same elements, features, and structures. The relative size and depiction of these elements, features, and structures may be exaggerated for clarity, illustration, and convenience.

### DETAILED DESCRIPTION

Since the disclosed embodiment may be modified and have several embodiments, specific example embodiments of the disclosure will be illustrated in the drawings and described in detail below. However, the disclosure is not limited to the specific example embodiments, but rather includes various modifications, equivalents, and/or alternatives of the example embodiments. Throughout the accompanying drawings, similar components will be denoted by similar reference numerals.

In describing the disclosure, when it is determined that a detailed description for well-known functions or configurations related to the disclosure may unnecessarily obscure the gist of the disclosure, the detailed description of the well-known functions or configurations may be omitted.

In addition, the following embodiments may be modified in several different forms, and the scope of the disclosure is not limited to the following embodiments. Rather, these embodiments make the disclosure thorough and complete, and are provided to completely transfer a technical understanding of the disclosure to those skilled in the art.

Terms used in the disclosure are used only to describe specific embodiments rather than limiting the scope of the disclosure. Singular forms are intended to include plural forms unless the context clearly indicates otherwise.

In the disclosure, the expressions “have”, “may have”, “include”, or “may include” indicate existence of a corresponding feature (for example, a numerical value, a function, an operation, or a component such as a part), and do not exclude existence of an additional feature.

In the disclosure, the expressions “A or B”, “at least one of A and/or B”, or “one or more of A and/or B”, may include all possible combinations of items enumerated together. For example, “A or B”, “at least one of A and B”, or “at least one of A or B” may indicate all of 1) a case in which at least one A is included, 2) a case in which at least one B is included, or 3) a case in which both of at least one A and at least one B are included.

The expressions “first” or “second” used in the disclosure may indicate various components regardless of a sequence and/or importance of the components, will be used only to distinguish one component from the other components, and do not limit the corresponding components.

When it is mentioned that any component (for example, a first component) is (operatively or communicatively) coupled to or is connected to another component (for example, a second component), it is to be understood that any component is directly coupled to another component or may be coupled to another component through the other component (for example, a third component).

Alternatively, when it is mentioned that any component (for example, a first component) is “directly coupled” or “directly connected” to another component (for example, a second component), it is to be understood that the other component (for example, a third component) is not present between any component and another component.

The expression “configured (or set) to” used in the disclosure may be replaced by the expressions “suitable for”, “having the capacity to” “designed to”, “adapted to”, “made to”, or “capable of” depending on a situation. A term “configured (or set) to” may not necessarily mean “specifically designed to” in hardware.

In some situations, an expression “a device configured to” may mean that the device may “work” together with other devices or components. For example, a phrase “processor configured (or set) to perform A, B, and C” may mean a dedicated processor (for example, an embedded processor) for performing the corresponding operations or a generic-purpose processor (for example, a central processing unit (CPU) or an application processor) that may perform the corresponding operations by executing one or more software programs stored in a memory device.

A display device according to some embodiments may include, for example, a television, a monitor, a smartphone, a tablet personal computer (PC), or a wearable device.

In the disclosure, the TFT including the TFT layer (or backplane) are not limited to a specific structure or type. That is, the TFT may also be implemented as LTPS TFT, oxide TFT, Si TFT (poly silicon, a-silicon), organic TFT and graphene TFT. Also, the TFT may be applied only by making P type (or N-type) MOSFET in Si wafer CMOS process.

Various elements and regions in the drawings are schematically illustrated. Therefore, the scope of the disclosure is not limited by relatively sizes or intervals illustrated in the accompanying drawings.

Hereinafter, embodiments of the disclosure will be described in detail with reference to the accompanying drawings so that those skilled in the art to which the disclosure pertains may easily practice the disclosure.

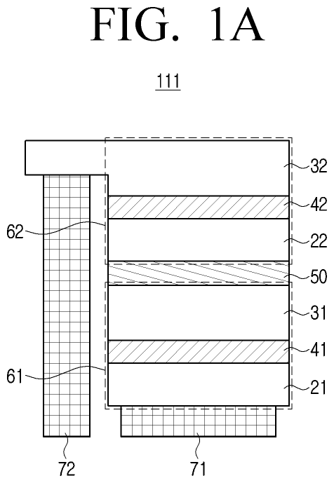

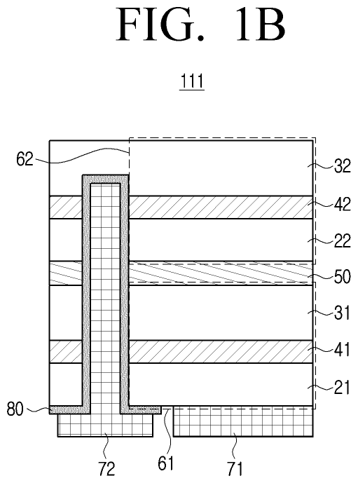

FIGS. 1A and 1B are cross-sectional views illustrating structures of a light emitting diode (LED) element 111 according to some embodiments.

As illustrated in FIGS. 1A and 1B, the LED element 111 includes a first light emitting cell 61, a second light emitting cell 62, a tunnel junction layer 50, a first electrode 71, and a second electrode 72.

The light emitting cells 61 and 62 refer to regions including a light emitting layer. The light emitting cells 61 and 62 may each be formed in respective portions of one LED element 111. According to FIGS. 1A and 1B, the first light emitting cell 61 includes a first n-type semiconductor layer 21, a first p-type semiconductor layer 31, and a first light emitting layer 41. The second light emitting cell 62 may include a second n-type semiconductor layer 22, a second p-type semiconductor layer 32, and a second emission layer 42. In FIGS. 1A and 1B, a structure in which the first and second n-type semiconductor layers 21 and 22 are formed beneath the first and second light emitting layers 41 and 42, respectively, and the first and second p-type semiconductor layers 31 and 32 are formed on the first and second light emitting layers 41 and 42, respectively, has been illustrated, but a positional relationship between these components may be reversely implemented. That is, the n-type semiconductor layers 21 and 22 may be formed on the light emitting layers 41 and 42, respectively, and the p-type semiconductor layers 31 and 32 may be formed beneath the light emitting layers 41 and 42, respectively. However, for convenience of explanation, a description will be provided for the configurations illustrated in FIGS. 1A and 1B.

Hereinafter, in a case where the first and second n-type semiconductor layers 21 and 22 and the first and second p-type semiconductor layers 31 and 32 do not need to be described separately, the first and second n-type semiconductor layers 21 and 22 and the first and second p-type semiconductor layers 31 and 32 may be collectively referred to as n-type semiconductor layers 21 and 22 and p-type semiconductor layers 31 and 32, respectively. In addition, the first and second light emitting layers 41 and 42, first and second electrodes 71 and 72, and the like, may be collectively referred to as light emitting layers 41 and 42, electrodes 71 and 72, and the like, respectively, if necessary.

The light emitting layers 41 and 42, the n-type semiconductor layers 21 and 22, and the p-type semiconductor layers 31 and 32 may be formed of various semiconductors having band gaps corresponding to specific regions in a spectrum. For example, a red LED element 111 having a light wavelength of 600 to 750 nm may include one or more layers based on an AlInGaP-based semiconductor. In addition, blue and green LED elements 111 having light wavelengths of 450 to 490 nm and 500 to 570 nm, respectively, may include one or more layers based on an AlInGaN-based semiconductor.

The n-type semiconductor layers 21 and 22 and the p-type semiconductor layers 31 and 32 may be implemented by compound semiconductors such as group III-V and group II-VI. Particularly, the n-type semiconductor layers 21 and 22 and the p-type semiconductor layers 31 and 32 may be implemented by nitride semiconductor layers. For example, the n-type semiconductor layers 21 and 22 and the p-type semiconductor layers 31 and 32 may be n-GaN semiconductor layers and p-GaN semiconductor layers, respectively. However, the n-type semiconductor layers 21 and 22 and the p-type semiconductor layers 31 and 32 according to the disclosure are not limited thereto, and may be formed of various materials according to various characteristics required for the LED element 111.

An n-type semiconductor is a semiconductor in which free electrons are used as carriers transferring electric charges, and may be manufactured by doping an n-type dopant such as Si, Ge, Sn, or Te. In addition, a p-type semiconductor is a semiconductor in which holes are used as carriers transferring electric charges, and may be manufactured by doping a p-type dopant such as Mg, Zn, Ca, or Ba.

The light emitting layers 41 and 42 are positioned between the n-type semiconductor layers 21 and 22 and the p-type semiconductor layers 31 and 32, respectively, and are layers in which electrons which are carriers of the n-type semiconductor layers 21 and 22 and holes which are carriers of the p-type semiconductor layers 31 and 32 meet each other. When the electrons and the holes meet each other in the light emitting layers 41 and 42, the electrons and holes are recombined with each other, such that potential barriers are formed. In addition, when the electrons and the holes transition to a lower energy level beyond the potential barriers depending on an applied voltage, the electrons and the holes emit light having corresponding wavelengths.

Here, the light emitting layers 41 and 42 may have a multi-quantum well (MQW) structure. However, the disclosure is not limited thereto, and the light emitting layers 41 and 42 may have various structures such as a single quantum well (SQW) structure or a quantum dot (QD) structure. In a case where the light emitting layers 41 and 42 are formed in the multi-quantum well structure, well layers/barrier layers of the light emitting layers 41 and 42 may be formed in a structure such as InGaN/GaN, InGaN/InGaN, or GaAs (InGaGs)/AlGaAs. However, the disclosure is not limited to such structures. The number of quantum wells included in the light emitting layers 41 and 42 is also not limited to a specific number.

According to an embodiment, the first light emitting layer 41 and the second light emitting layer 42 may have matching band gap characteristics. That is, the first light emitting layer 41 and the second light emitting layer 42 may emit light having the same wavelength corresponding to the same band gap, For example, the first light emitting layer 41 and the second light emitting layer 42 may have band gap characteristics corresponding to a wavelength of red light.

The light emitted from the first light emitting layer 41 and the second light emitting layer 42 is transmitted through the respective semiconductor layers in an overlapping form, and is then emitted to an upper surface of the LED element 111. That is, the upper surface of the LED element 111, more specifically, an upper surface of the second light emitting cell 62 becomes a light emitting surface of the LED element 111.

Therefore, a plurality of semiconductor layers stacked (or laminated) on the first light emitting layer 41 need to be formed to transmit the light emitted by the first light emitting layer 41 and the second light emitting layer 42. Specifically, materials of a semiconductor layer formed on the first light emitting layer 41, more specifically the first n-type semiconductor layer 21 and the first p-type semiconductor layer 31, and the second light emitting layer 42, specifically the second n-type semiconductor layer 22 and the second p-type semiconductor layer 32, may be selected to transmit the light emitted by the first light emitting layer 41 and the second light emitting layer 42.

For example, in a case where the LED element 111 is manufactured in the structures illustrated in FIGS. 1A and 1B, materials of the first p-type semiconductor layer 31, the tunnel junction layer 50, the second n-type semiconductor layer 22, the second light emitting layer 42, and the second p-type semiconductor layer 32 need to be selected to have a property capable of transmitting the light emitted by the first light emitting layer 41 and the second light emitting layer 42.

The tunnel junction layer 50 may be formed between the first light emitting cell 61 and the second light emitting cell 62, and serves to electrically connect the first light emitting cell 61 and the second light emitting cell 62 to each other. Specifically, the tunnel junction layer 50 may include an n⁺-type semiconductor layer and a p⁺-type semiconductor layer formed by heavily doping an n-type dopant or a p-type dopant. In addition, when a concentration of impurities included in the n-type semiconductor layer and the p-type semiconductor layer is increased to about 10¹⁹/cm³ or more, an energy barrier between the first p-type semiconductor layer 31 and the second n-type semiconductor layer 22 may be lowered. Therefore, a current may flow due to a tunneling effect in which the electrons tunnel through the energy barrier.

For example, in the case of the LED element 111 illustrated in FIGS. 1A and 1B, a current may flow due to the tunneling effect even at an interface of an n-p tunnel junction to which a reverse voltage is applied. In other words, the first light emitting cell 61 and the second light emitting cell 62 may be connected to each other in series through the tunnel junction layer 50. A specific material included in the tunnel junction layer 50 is not limited.

The first electrode 71 and the second electrode 72 may be electrically connected to the first light emitting cell 61 and the second light emitting cell 62, respectively. Here, the first electrode 71 may be connected to one of the first n-type semiconductor layer 21 or the first p-type semiconductor layer 31 included in the first light emitting cell 61. In addition, the second electrode 72 may be connected to one of the second n-type semiconductor layer 22 or the second p-type semiconductor layer 32 included in the second light emitting cell 62.

Referring to FIGS. 1A and 1B, the first electrode 71 may be connected to the first n-type semiconductor layer 21 included in the first light emitting cell 61, and the second electrode 72 may be connected to the second p-type semiconductor layer 32 included in the second light emitting cell 62. Specifically, the first electrode 71 may be electrically connected to the first n-type semiconductor layer 21 by forming an ohmic contact with the first n-type semiconductor layer 21, and the second electrode 72 may be electrically connected to the second p-type semiconductor layer 32 by forming an ohmic contact with the second p-type semiconductor layer 32. In this case, the first electrode 71 and the second electrode 72 may be referred to as an n electrode and a p electrode, respectively.

When a voltage is applied through the first electrode 71 and the second electrode 72, the electrons in the n-type semiconductor layers 21 and 22 move toward a positive terminal, and the holes in the p-type semiconductor layers 31 and 32 move toward a negative terminal. As a result, minority carriers are formed causing current flow. In addition, as described above, the current may also flow due to the tunneling effect at the interface of the n-p tunnel junction layer 50, resulting in current flow through the entire LED element 111.

The LED element 111 according to an embodiment of the disclosure may further include a contact hole and an insulating layer 80, and the first electrode 71 or the second electrode 72 may be connected to the second light emitting cell 62 through the contact hole.

Specifically, as illustrated in FIG. 1B, the contact hole may be formed to extend through the first light emitting cell 61, the tunnel junction layer 50, and a part of the second light emitting cell 62. For example, the contact hole may be formed through the first n-type semiconductor layer 21, the first light emitting layer 41, the first p-type semiconductor layer 31, the tunnel junction layer 50, the second n-type semiconductor layer 22, the second light emitting layer 42, and a part of the second p-type semiconductor layer 32. In this case, the second electrode 72 may be electrically connected to the second p-type semiconductor layer 32 through the contact hole.

As illustrated in FIG. 1B, the insulating layer 80 may be formed on a surface of the contact hole to stabilize characteristics of the LED element 111. Specifically, the insulating layer 80 may be formed on the surface of the contact hole to serve to electrically insulate the second electrode 72 from the first n-type semiconductor layer 21, the first light emitting layer 41, the first p-type semiconductor layer 31, the tunnel junction layer 50, the second n-type semiconductor layer 22, and the second light emitting layer 42. Therefore, the insulating layer 80 may be formed of an insulating material such as Al₂O₃, SiN, and SiO₂. However, the insulating layer 80 is not limited to a specific material.

Although not illustrated in FIGS. 1A and 1B, an LED element 111 according to an embodiment of the disclosure may further include a component for increasing luminous efficiency of the LED element 111, such as a reflective layer. For example, the LED element 111 may further include a reflective layer formed to reflect the light emitted from the first light emitting layer 41 and the second light emitting layer 42 toward the light emitting surface of the LED element 111. Specifically, the reflective layer may be formed on sidewalls of the LED element 111 and a surface of the LED element 111 opposite to the light emitting surface of the LED element 111. In addition, the reflective layer may be formed as a metal reflector or with a distributed-bragg-reflector structure.

As illustrated in FIGS. 1A and 1B, the LED element 111 may be implemented in a flip-chip type in which the first electrode 71 and the second electrode 72 are arranged toward the surface of the LED element 111 opposite to the light emitting surface of the LED element 111. However, the LED element 111 is not limited thereto, and may also be implemented as a lateral type in which the first electrode 71 and the second electrode 72 are horizontally arranged on the light emitting surface or a vertical type in which the first electrode 71 and the second electrode 72 are vertically arranged.

A size of the LED element 111 is not limited, but according to an embodiment, the LED element 111 may be a micro LED element 111. Specifically, the LED element 111 may be implemented to have horizontal and vertical lengths in the range of 1μm to 100 pm.

As described above, the LED element 111 according to an embodiment has a structure in which two LEDs (light emitting cells 61 and 62) are vertically stacked through the tunnel junction layer 50, and thus has the same effect as two LEDs connected to each other in series in one LED element 111. Therefore, the luminous efficiency, specifically, external quantum efficiency, of the LED element 111 may be improved. Furthermore, since the improvement in luminous efficiency is equally applied in a low current state, particularly in a micro LED display device requiring low current driving, low current luminous efficiency is improved when compared to related art.

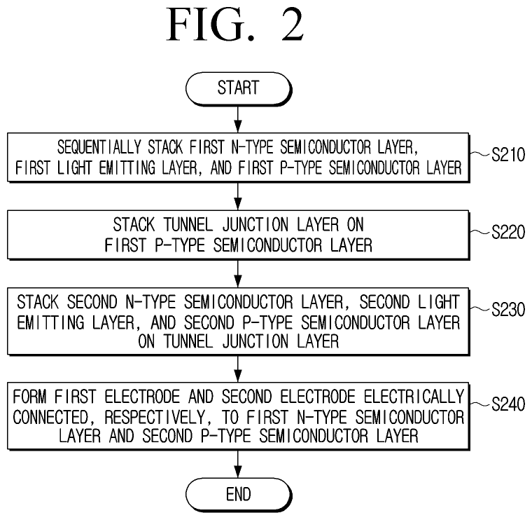

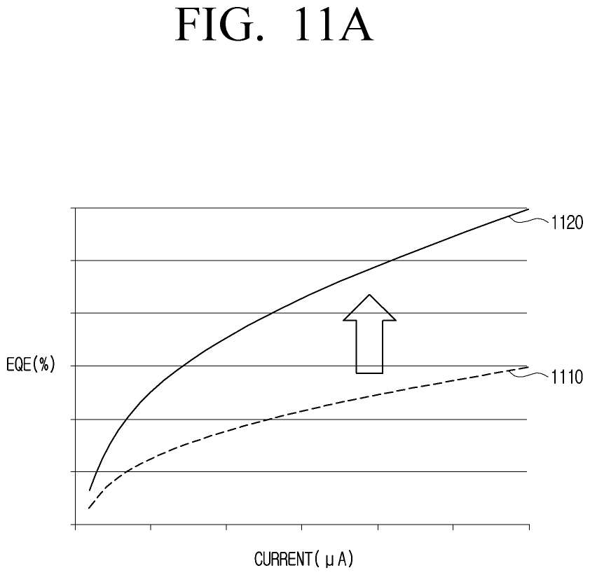

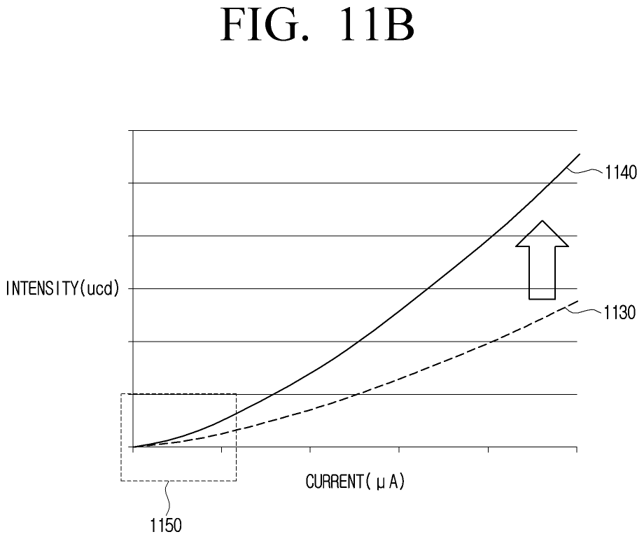

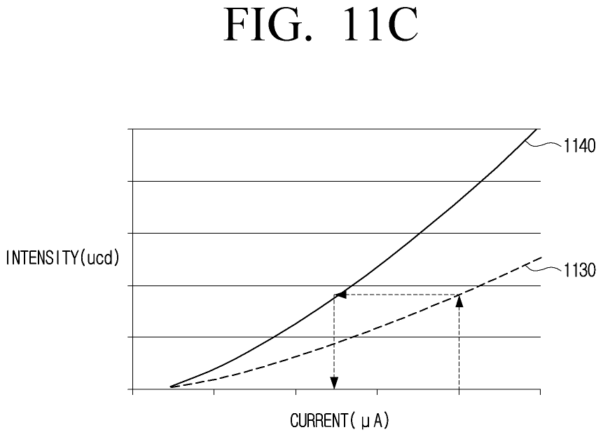

Furthermore, driving current and consumed power of a display device including LED element 111 may be decreased. A more detailed discussion of the improvements over the related art will be described later with reference to FIGS. 11A through 11C. Hereinafter, a method of manufacturing an embodiment of an LED element 111 will be described with reference to FIGS. 2 to 4C.

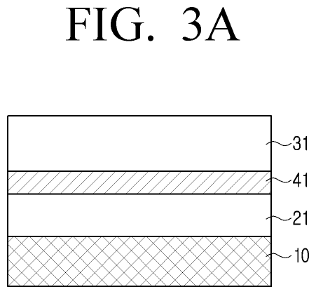

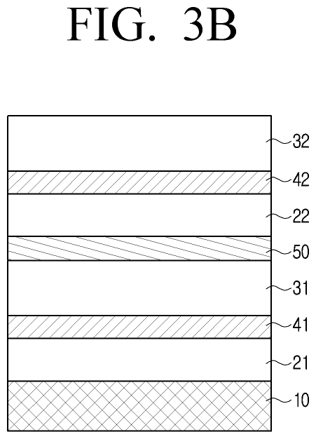

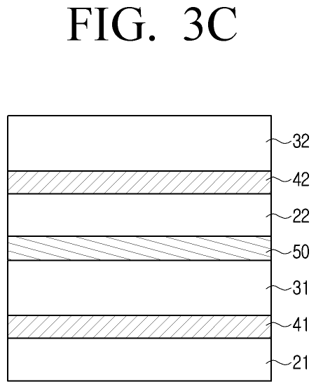

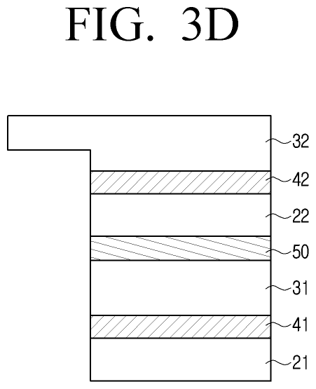

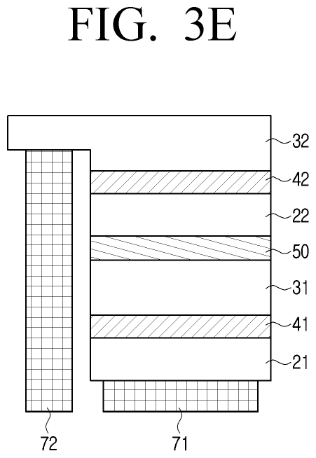

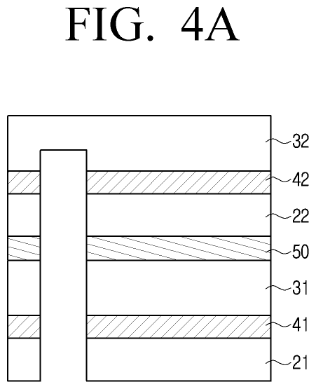

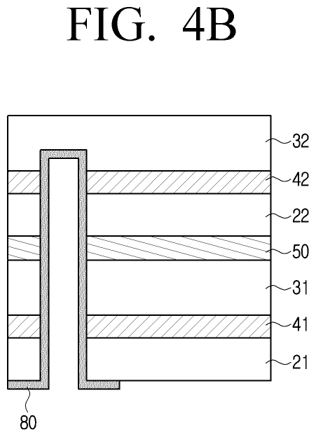

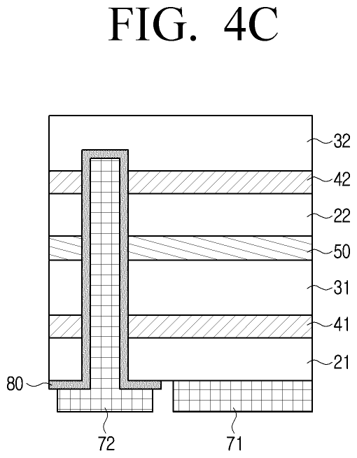

FIG. 2 is a flow chart illustrating a method of manufacturing an LED element 111 according to an embodiment, and FIGS. 3A to 3E and 4A to 4C are cross-sectional views illustrating each operation of the method of manufacturing an LED element 111 according to an embodiment.

The structure of the LED element 111 according to an embodiment. Additionally, the characteristics, the functions and the like of each layer included in the LED element 111 have been described above in a description for FIGS. 1A and 1B, and an overlapping description will thus be omitted except when necessary for clearly describing the disclosure.

A substrate 10 used in the method of manufacturing an LED element 111 according to an embodiment may be a substrate formed of a material suitable for growth of a semiconductor, a carrier wafer, or the like. Specifically, the substrate 10 may be formed of a material such as sapphire (Al₂SO₄), Si, SiC, GaN, GaAs, or ZnO. However, a material of the substrate 10 used in the disclosure is not limited to a specific material.

The first n-type semiconductor layer 21, the first light emitting layer 41, and the first p-type semiconductor layer 31 may be sequentially stacked on the substrate 10 (operation S210), as illustrated in FIG. 3A. After the first n-type semiconductor layer 21, the first light emitting layer 41, and the first p-type semiconductor layer 31 are sequentially stacked on the substrate 10, the tunnel junction layer 50 may be stacked on the first p-type semiconductor layer 31 (operation S220). Following formation of the tunnel junction layer 50, the second n-type semiconductor layer 22, the second light emitting layer 42, and the second p-type semiconductor layer 32 may be sequentially formed on the tunnel junction layer 50 (operation S230), as illustrated in FIG. 3B. The stacking may be performed by a technology such as metal organic chemical vapor deposition (MOCVD), metal organic vapor phase epitaxy (MOVPE), or molecular beam epitaxy (MBE).

When the second n-type semiconductor layer 22, the second light emitting layer 42, and the second p-type semiconductor layer 32 are sequentially formed on the tunnel junction layer 50, the substrate 10 for growth of a semiconductor layer may be removed, as illustrated in FIG. 3C, and a region for forming the second electrode 72 may be etched, as illustrated in FIG. 3D. Specifically, a region to be etched may be patterned by a photoresist process before the etching is performed, and the etching may be performed using a technology such as wet etching or dry etching. For example, the etching may be performed using a dry etching technology such as reactive ion etching (RIE), electro-cyclotron resonance (ECR), inductively coupled plasma reactive ion etching (ICP-RIE), or chemically assisted ion-beam etching (CAIBE).

Following the etching, as illustrated in FIG. 3E, the first electrode 71 and the second electrode 72 may be formed electrically connected to the first light emitting cell 61 and the second light emitting cell 62, respectively (operation S240). Specifically, the first electrode 71 and the second electrode 72 may be formed at a location toward the surface of the LED element 111 opposite to the light emitting surface of the LED element 111. That is, the first electrode 71 and the second electrode 72 may be formed at a location removed from the light emitting surface of the LED element. The first electrode 71 and the second electrode 72 may be formed by various process technologies such as sputtering, evaporation, and spin coating performed on electrode materials such as Al, Ti, Ni, Pd, Ag, Au, Au—Ge, indium-tin-oxide (ITO), and ZnO.

According to another embodiment of the disclosure, the LED element 111, shown in FIG. 1B, may be manufactured in a structure in which it further includes a contact hole. In this case, an operation of forming the contact hole by etching as illustrated in FIG. 4A may be performed after the operation of FIG. 3C.

In a case where the contact hole is formed, the insulating layer 80 may be further formed on the surface of the contact hole, as illustrated in FIG. 4B. The first electrode 71 and the second electrode 72 formed electrically connected to the first light emitting cell 61 and the second light emitting cell 62, respectively. The first electrode 71 and the second electrode 72 may be formed by filling the contact hole with an electrode material (operation S240), as illustrated in FIG. 4C.

In a case of an operation of evaporating or forming a plurality of components equal to each other as in an operation of forming the first electrode 71 and the second electrode 72 as described above, there may be no time-series element between two operations. In addition, the order of the method of manufacturing an LED element as described above may be changed for achieving an object of the disclosure.

As described above, a process technology used in the manufacture of the LED element 111 according to the disclosure has a very high compatibility with a process technology used in the manufacture of a general flip-chip type LED element.

A display panel according to an embodiment may be manufactured using a general transfer process such as an electrostatic manner, a stamp manner, a printing manner, or a metal bonding manner. Accordingly, the LED element 111 may have a high compatibility with a process of manufacturing an existing micro LED display panel. Therefore, a possibility that the LED element 111 will be utilized as a light emitting light source of a display device is increased.

An embodiment in which the LED element 111 includes the first light emitting cell 61 and the second light emitting cell 62 has been described hereinabove, but the disclosure is not limited thereto. That is, according to another embodiment, the LED element 111 may also be manufactured in a structure in which it includes two or more light emitting cells.

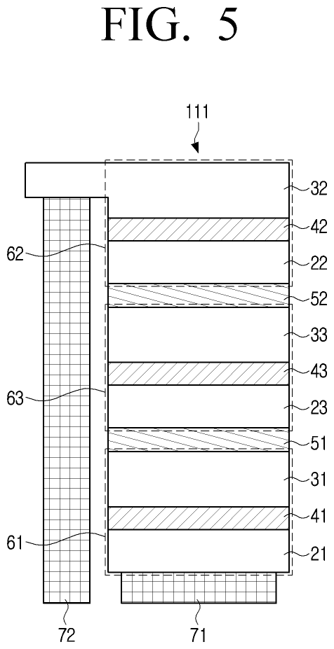

FIG. 5 is a cross-sectional view illustrating a structure of an LED element 111 including three light emitting cells. Specifically, the LED element 111 may further include a third light emitting cell 63 together with the first light emitting cell 61 and the second light emitting cell 62.

The third light emitting cell 63 may be formed between the first light emitting cell 61 and the second light emitting cell 62, and may include a third light emitting layer 43. Specifically, the third light emitting cell 63 may include the third light emitting layer 43, a third n-type semiconductor layer 23 formed on a surface of the third light emitting layer 43 that is above or beneath the third light emitting layer 43, and a third p-type semiconductor layer 33 formed on a surface of the third light emitting layer 43 opposite to a surface of the third light emitting layer 43 on which the third n-type semiconductor layer 23 is formed. In addition, in this case, the LED element 111 may include a first tunnel junction layer 51 formed between the first light emitting cell 61 and the third light emitting cell 63 and a second tunnel junction layer 52 formed between the second light emitting cell 62 and the third light emitting cell 63.

The first light emitting layer 41, the second light emitting layer 42, and the third light emitting layer 43 may have matching band gaps. That is, the first light emitting layer 41, the second light emitting layer 42, and the third light emitting layer 43 may have the same band gap, and emit light having the same wavelength corresponding to the same band gap. For example, the first light emitting layer 41, the second light emitting layer 42, and the third light emitting layer 43 may have a band gap corresponding to a wavelength of red light.

In addition, some embodiments of the LED element 111, shown in FIGS. 1A and 1B, including the first light emitting cell 61 and the second light emitting cell 62, may be similarly applied to the LED element 111, shown in FIG. 5, further including the third light emitting cell 63 together with the first light emitting cell 61 and the second light emitting cell 62.

The LED element 111 and the method of manufacturing the LED element 111 according to example embodiments have been described above. Hereinafter, a display device including the LED element 111, and more specifically, a display panel including the LED element 111 will be described.

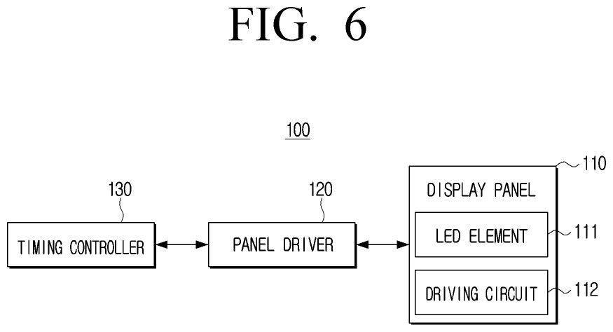

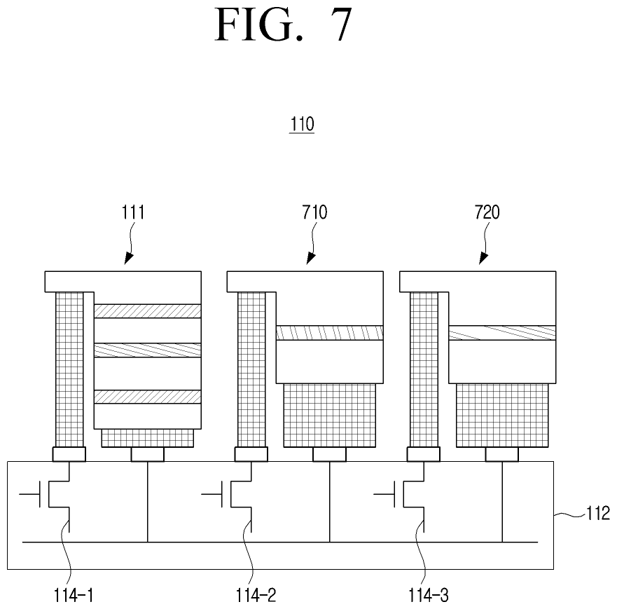

FIG. 6 is a block diagram illustrating a schematic configuration of a display device 100 according to an embodiment, and FIG. 7 is a view illustrating a structure of a display panel 110 according to an embodiment.

The display device 100 according to an embodiment may include at least one of a television, a monitor, a smartphone, or a wearable device. Furthermore, any type of device may be included in the display device 100 as long as it may display visual information through the display panel 110.

Referring to FIG. 6, the display device 100 may include the display panel 110, a panel driver 120, and a timing controller 130.

The display panel 110 displays an image based on input from the panel driver 120. In addition, the display panel 110 includes a plurality of LED elements 111 and a driving circuit 112 for driving each of the plurality of LED elements 111. In addition, the driving circuit 112 may include a plurality of switching elements.

At least one of the plurality of LED elements 111 may be the LED element 111 having the structure described with reference to FIGS. 1A to 5. For convenience of explanation, in the disclosure, an LED element 111 having such a structure is referred to as a first LED element 111. Specifically, the first LED element 111 may include a first light emitting cell including a first light emitting layer, a tunnel junction layer formed on the first light emitting cell, a second light emitting cell formed on the tunnel junction layer that includes a second light emitting layer, a first electrode electrically connected to the first light emitting cell, and a second electrode electrically connected to the second light emitting cell. In addition, the first light emitting cell and the second light emitting cell may be electrically connected to each other through the tunnel junction layer. Further, the first LED element 111 may be a flip-chip type LED element in which the first electrode and the second electrode are arranged toward a surface of the first LED element 111 opposite to a light emitting surface of the first LED element 111.

Alternatively, at least one of the others of the plurality of LED elements may be an LED element including one light emitting layer. For convenience of explanation, in the specification, such an LED element is referred to as a second LED element. Specifically, the second LED element may include a general LED element having one light emitting layer, an n-type semiconductor layer formed above or beneath the light emitting layer, and a p-type semiconductor layer formed on a surface of the one light emitting layer opposite to a surface of the one light emitting layer on which the n-type semiconductor layer is formed.

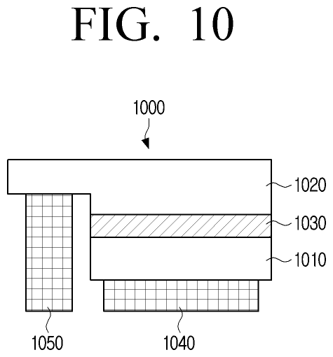

FIG. 7 illustrates an example of a structure of a display panel 110 according to an embodiment, specifically, a structure of a display panel including both of the first LED element 111 and the second LED elements 710 and 720. Specifically, in FIG. 7, each of the second LED elements 710 and 720 may be a general LED element as described later with reference to FIG. 10.

According to an embodiment, a light emitting surface of the first LED element 111 and a light emitting surface of the second LED elements 710 and 720 may be formed to have corresponding height. Specifically, the second LED elements 710 and 720 include one n-type semiconductor layer, one p-type semiconductor layer, and one light emitting layer unlike the first LED element 111 which includes a first light emitting cell and a second light emitting cell. Accordingly, a difference may be generated between a height of the first LED element 111 and a height of the second LED elements 710 and 720. For example, in a case where the LED element 111 is implemented by a micro LED, a height difference of about of 5 μm to 10 μm may be generated between the first LED element 111 and the second LED elements 710 and 720.

In the embodiment illustrated in FIG. 7, the difference between the height of the first LED element 111 and the height of the second LED elements 710 and 720 may be decreased by adjusting heights of first and second electrodes included in each of the second LED elements 710 and 720. Furthermore, the difference between the height of the first LED element 111 and the height of the second LED elements 710 and 720 may be decreased by various methods such as a method of adjusting a black matrix (BM) layer formed on the first LED element 111 and the second LED elements 710 and 720.

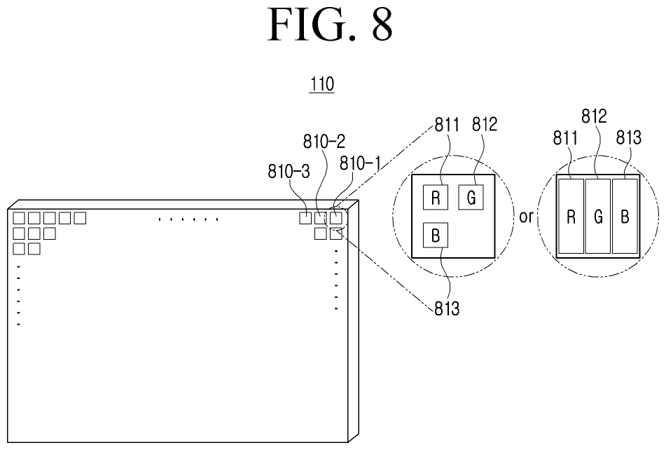

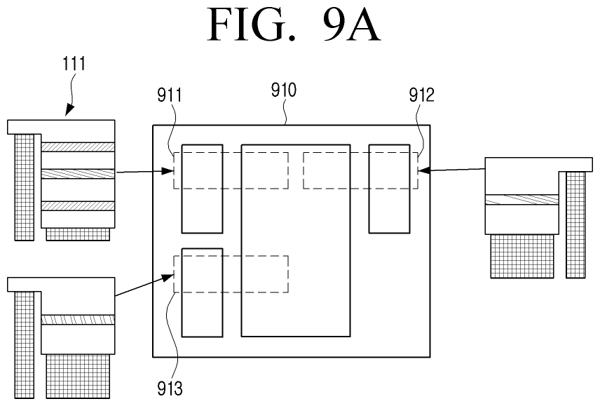

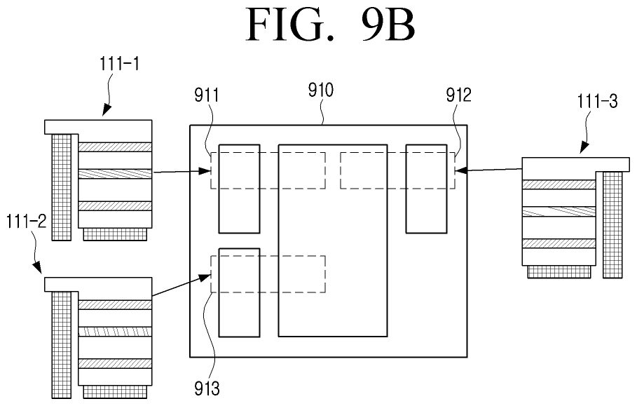

The display panel 110 may include a plurality of pixels arranged in a matrix form, each of the plurality of pixels may include a plurality of sub-pixels, and the plurality of sub-pixels may be driven by the plurality of LED elements as described above. An embodiment related to a pixel configuration of the display panel 110 is described with reference to FIGS. 8 to 9B.

In FIG. 7 and the subsequent drawings, reference numerals regarding the elements of the LED element 111 are omitted to more clearly illustrate a relationship between electrodes of the plurality of LED elements and the display panel 110. A description for the detailed configuration of the LED element 111 has been as described above with reference to FIGS. 1A to 5.

The driving circuit 112 refers to a circuit for driving the plurality of LED elements 111, 710, and 720. The plurality of LED elements 111, 710, 720 may be mounted on a driving circuit layer including the driving circuit 112, and specifically, each of the plurality of LED elements 111, 710, and 720 may be electrically connected to the driving circuit 112.

The driving circuit 112 may include the plurality of switching elements together with a plurality of electrodes, a plurality of circuit elements, and the like. The switching elements may be semiconductor elements configured to control the driving of the plurality of LED elements 111, 710, and 720 included in the display panel 110, and serve as switches for individual pixels of the display device 100. As such switching elements, thin film transistors (TFTs) 114-1, 114-2, and 114-3 as illustrated in FIG. 7 may be used.

The display panel 110 may be driven in a passive matrix manner or an active matrix manner, and the driving circuit 112 may thus be designed according to a driving manner of the display panel 110.

The panel driver 120 includes a plurality of driver integrated circuits (ICs), and controls the driving of the display panel 110 through the plurality of driver ICs. Specifically, the plurality of driver ICs included in the panel driver 120 may control the light emission of the plurality of LED elements each connected to the driving circuit 112 by driving the driving circuit 112.

Although not illustrated in FIG. 6, the panel driver 120 may further include a graphic random access memory (GRAM) and a power generating circuit. The GRAM may serve as a memory for temporarily storing data to be input to the driver IC. In addition, the power generating circuit serves to generate a voltage for driving the display panel 110 and suppling the generated voltage to the driver IC.

The timing controller 130 controls the panel driver 120. Specifically, the timing controller 130 may adjust an image data signal to a signal required by the panel driver 120 and may transmit the adjusted signal to the panel driver 120. In addition, the timing controller 130 may further include a field programmable gate array (FPGA), an application specific integrated circuit (SIC) or the like. The timing controller 130 may be called a timing controller (T-CON), a data hub, a receiving card, a controller, or the like, in the related art, but may be applied to the disclosure regardless of a name thereof as long as it may control the panel driver 120 within the scope in which an objective of the disclosure may be achieved.

Although not illustrated in FIG. 6, the display device 100 may further include a memory (not illustrated) and a processor (not illustrated). The memory (not illustrated) may store at least one command related to control of the display device 100, software related to an operation of the display device 100, image data, and the like. In addition, the processor (not illustrated) may control a general operation of the display device 100.

FIG. 8 is a view illustrating a pixel configuration of the display panel 110 according to an embodiment of the disclosure, and FIGS. 9A and 9B are views illustrating the pixel configuration of the display panel 110 according to an embodiment of the disclosure together with LED elements 111 corresponding to respective sub-pixels.

As illustrated in FIG. 8, an embodiment of the display panel 110 may include a plurality of pixels 810-1, 810-2, and 810-3 arranged in a matrix form, and each of the plurality of pixels 810-1, 810-2, and 810-3 may include an R sub-pixel 811, a G sub-pixel 812, and a B sub-pixel 813. An example in which a plurality of sub-pixels are arranged in a 2×2 matrix form within one pixel and an example in which a plurality of sub-pixels are arranged in a 3x1 matrix form within one pixel have been illustrated in FIG. 8, but the disclosure is not limited thereto.

The R sub-pixel 811, the G sub-pixel 812, and the B sub-pixel 813 may correspond to the LED elements, respectively. Indicating that the respective sub-pixels 911, 912, and 913 correspond to the LED elements means that the respective sub-pixels 911, 912, and 913 may be operated by driving the LED elements. For example, as illustrated in FIGS. 9A and 9B, at least one of the R sub-pixel 911, the G sub-pixel 912, or the B sub-pixel 913 configuring one pixel 910 may correspond to an embodiment of the LED element 111. Hereinafter, as defined with reference to FIG. 7, an embodiment of the LED element 111 according to diverse embodiments of the disclosure will be referred to as a first LED element 111, and a general LED element will be described as a second LED element.

For example, as illustrated in FIG. 9A, the R sub-pixel may correspond to the first LED element 111, and each of the G sub-pixel and the B-sub pixel may correspond to the second LED element. In this case, as described above with reference to FIG. 7, heights of first and second electrodes included in the second LED elements may be adjusted so that a light emitting surface of the first LED element 111 and a light emitting surface of the second LED elements may be formed to have a corresponding height. As another example, as illustrated in FIG. 9B, all of the R sub-pixels, the G sub-pixels, and the B sub-pixels may correspond to the first LED element 111. In addition, a corresponding relationship between the sub-pixels and the LED elements according to the disclosure may be implemented in embodiments. For example, an embodiment may have in which the G sub-pixels correspond to the first LED element and each of the R sub-pixels and the B sub-pixels correspond to the second LED element. Alternatively, an embodiment may have each of the R sub-pixels and the G sub-pixels correspond to the first LED element and the B sub-pixels correspond to the second LED element.

As another example, in a multicolor LED element in which one LED element may emit a plurality of light having different wavelengths, the structure of an LED element 111 may be applied to at least a part of the LED element. For example, one LED element may include a plurality of regions each emitting red light, green light, and blue light, and may be implemented in a form in which the structure of the LED element 111 is applied to the region emitting the red light and a structure of a general LED element is applied to the regions emitting the green light and the blue light.

As described above, in a case where the sub-pixel included in the display panel 110 corresponds to the LED element 111, particularly, when the LED element corresponding to the R sub-pixel is implemented by the LED element 111, a driving current and power consumption of the display device 100 may be remarkably decreased relative to the LED elements of the related art. Hereinafter, the performance of the display device 100 as compared with the related art will be described in detail.

FIG. 10 is a view illustrating a general LED element 1000 according to the related art, and FIGS. 11A to 11C are views for describing the performance of the LED element 111 according to an embodiment the disclosure and the display device according to the disclosure as compared with the general LED of the related art.

FIG. 10 is a cross-sectional view illustrating a structure of the second LED element 1000 as presented in FIGS. 7 and 9A, that is, a general LED element according to the related art. As illustrated in FIG. 10, the general LED element 1000 according to the related art includes a single light emitting layer 1030, an n-type semiconductor layer 1010 formed on or beneath the single light emitting layer 1020, and a p-type semiconductor layer 1020 formed on a surface of the single light emitting layer 1030 opposite to a surface of the single light emitting layer 1030 on which the n-type semiconductor layer 1010 is formed. A first electrode is electrically connected to the n-type semiconductor layer 1010 and a second electrode 1050 is electrically connected to the p-type semiconductor layer.

In a case of the general LED element according to the related art, more specifically, a flip-chip type micro LED element, external quantum efficiency (EQE) of the LED element rapidly decreases in a low current state. Here, the EQE is defined by a value obtained by dividing the number of emitted photons by the number of injected electrons, and is a function of internal quantum efficiency (IQE) and light extraction efficiency (LEE) of the LED element. In addition, luminous efficiency of the LED element is changed depending on the IQE and the EQE. EQE of the general LED element according to the related art rapidly decreases, especially in a low current section of about 10 μA or less, and EQE of a red general LED element is lower than that of a green general LED element and a blue general LED element. The red LED element, the green LED element, and the blue LED element refer to LED elements capable of emitting red light, green light, and blue light, respectively.

Further, for example, in a case of driving a display panel at a luminance of 150 nit (Cd/cm²) under a TFT driving voltage of about 4 V, the red LED element occupies about 39% of a driving current, which is higher than about 34% occupied by the green LED element and about 27% occupied by the blue LED element. Furthermore, the red LED element occupies about 42% of consumed power for driving a TFT, which is higher than about 33% occupied by the green LED element and about 25% occupied by the blue LED element.

As described above, particularly, in the low current section, the EQE of the red LED element is lower than that of the green LED element and the blue LED element. However, light distribution characteristics of the red LED element are close to Lambertian characteristics, and it is thus difficult to satisfy high brightness characteristics recently required in a display device only by improving light distribution characteristics of the LED element itself

Therefore, a method of forming the red LED element having a wide light emitting area may be considered. However, such a method is directly against a trend toward miniaturization and high integration of the display device. Accordingly, a method of horizontally connecting a plurality of red LED elements to each other in series may be considered. However, according to such a method, problems such as an increase in a manufacturing cost of the display device and a decrease in a yield of the display device occur.

When a high driving current is allowed to flow to the red LED element to overcome low luminous efficiency of the red LED element, problems such as an increase in consumed power and heat generation of the display device are caused. For example, in a micro LED display device using a large number of LED elements, one of the main challenges is to decrease a drive current and consumed power.

Therefore, there is a need for a technology of manufacturing a high efficiency LED element for decreasing the driving current and the consumed power of the display device including the LED elements, and the disclosure has been devised according to such a need. Hereinafter, effects of the LED element 111 according to an embodiment of the disclosure and the display device 100 according to the disclosure as compared with a display device according to the related art will be described.

FIGS. 11A to 11C show graphs for describing the performance of the LED element 111 according to an embodiment of the disclosure, more specifically, a flip-chip type red micro LED element 111, as compared with a red general micro LED element according to the related art.

Graphs, as illustrated in FIGS. 11A to 11C, and analysis results of these graphs may be slightly changed according to characteristic of specific LED elements, experimental conditions, and the like, but it is theoretically and experimentally easy for those skilled in the art to which the disclosure pertains to prove the results as described later.

FIG. 11A is a graph for comparing luminous efficiency, more specifically, EQE, of the LED element 111 according to an embodiment of the disclosure and luminous efficiency of the general LED element according to the related art with each other. Specifically, a lower line 1110 of FIG. 11A represents the luminous efficiency of the general LED element according to the related art, and an upper line 1120 of FIG. 11A represents the luminous efficiency of the LED element 111 according to an embodiment of the disclosure. In addition, as illustrated in FIG. 11A, the x axis indicates the current (μA) and a y axis indicates EQE (%).

Referring to FIG. 11A, it is shown that the luminous efficiency of the LED element 111 according to an embodiment of the disclosure is higher in all current sections than that of the general LED element according to the related art.

FIGS. 11B and 11C are graphs for comparing an intensity of the LED element 111 according to an embodiment of the disclosure to an intensity of the general LED element according to the related art. Specifically, a lower line 1130 of FIG. 11B represents the intensity of the general LED element according to the related art, and an upper line 1140 of FIG. 11B represents the intensity of the LED element 111 according to an embodiment of the disclosure. FIG. 11C is an enlarged region of the graph shown in FIG. 11B indicated by dotted line 1150 of FIG. 11B. In addition, as illustrated in FIGS. 11B and 11C, the x axis indicates a current (μA) and the y axis indicates an intensity (μCd).

Referring to FIG. 11B, it is shown that the intensity of the LED element 111 according to an embodiment the disclosure is higher in all current sections than that of the general LED element according to the related art. In addition, referring to FIG. 11C, it is shown that a driving current of the LED element 111 according to an embodiment of the disclosure is lower than that of the general LED element according to the related art on the assumption that the intensities are the same as each other in a low current state.

In addition, when the driving current of the disclosed display device is decreased, the consumed power of the display device may be decreased accordingly. Additionally, a larger TFT driving voltage results in a greater decrease in consumed power. As such, the heat generation of the display device will be decreased together with the decrease in the consumed power.

In summary, the LED element 111 according to an embodiment of the disclosure as described above has a structure in which two LEDs are vertically stacked through the tunnel junction layer, and thus has the same effect as two LEDs connected to each other in series in one LED element. Specifically, the luminous efficiency, specifically, the EQE, of the LED element 111 may be improved.

In addition, according to the disclosure, the driving current and the consumed power of the display device including the LED element 111 may be decreased when compared with the related art, particularly in the micro LED display device requiring the low current driving.

In addition, as described above, the process technology used in the manufacture of the LED element 111 according to an embodiment of the disclosure has a very high compatibility with the process technology used in the manufacture of the general flip-chip type LED element. Furthermore, the LED element 111 according to an embodiment of the disclosure has a high compatibility with a process of manufacturing the existing micro LED display panel. Therefore, a possibility that the LED element 111 will be utilized as a light emitting light source of the display device is high.

In addition, the LED element 111 according to the disclosure is the flip-chip type LED element 111, which has not only a structure advantageous for miniaturization, lightness, and high integration of a single element, but may also improve luminous efficiency, efficiency of a transfer process, and the like, in manufacturing the display device. Therefore, an applicability of the flip-chip type LED element 111 particularly to a micro LED field that has become recently prominent is high.

A display module including LED elements 111 according to an embodiment of the disclosure may be installed in and applied to a wearable device, a portable device, a handheld device, and an electronic product or an electrical component requiring various displays, in a single unit. Additionally, the display module may be applied to a display device such as a monitor for a PC, a high resolution TV, a signage, and an electronic display through a plurality of assembly arrangements in a matrix type.

Each of the components (for example, modules or programs) according to some embodiments of the disclosure as described above may include a single entity or a plurality of entities, and some of the corresponding sub-components described above may be omitted or other sub-components may be further included in some embodiments. Alternatively or additionally, some of the components (for example, the modules or the programs) may be integrated into one entity, and may perform functions performed by the respective corresponding components before being integrated in the same or similar manner.

Operations performed by the modules, the programs, or other components according to some embodiments may be executed in a sequential manner, a parallel manner, an iterative manner, or a heuristic manner, at least some of the operations may be performed in a different order or be omitted, or other operations may be added.

Although embodiments of the disclosure have been illustrated and described hereinabove, the disclosure is not limited to the abovementioned specific embodiments, but may be variously modified by those skilled in the art to which the disclosure pertains without departing from the gist of the disclosure as disclosed in the accompanying claims. These modifications should also be understood to fall within the scope of the disclosure.

What is claimed is:

1. A light emitting diode (LED) element comprising:
a first light emitting cell comprising a first light emitting layer;
a tunnel junction layer formed on the first light emitting cell;
a second light emitting cell formed on the tunnel junction layer and comprising a second light emitting layer;
a first electrode electrically connected to the first light emitting cell; and
a second electrode electrically connected to the second light emitting cell,
wherein the first light emitting cell is electrically connected to the second light emitting cell through the tunnel junction layer, and
the LED element is a flip-chip type LED element in which the first electrode and the second electrode are arranged toward a surface of the LED element opposite to a light emitting surface of the LED element.

2. The LED element as claimed in claim 1, wherein the first light emitting layer and the second light emitting layer have matching band gap characteristics.

3. The LED element as claimed in claim 2, wherein the matching band gap characteristics of first light emitting layer and the second light emitting layer correspond to a wavelength of red light.

4. A display panel comprising:
a plurality of LED elements; and
a driving circuit configured to drive the plurality of LED elements,
wherein the plurality of LED elements comprises a first LED element,
the first LED element comprises:
a first light emitting cell comprising a first light emitting layer;
a first tunnel junction layer formed above the first light emitting cell;
a second light emitting cell formed on a surface of the first tunnel junction layer opposite to the first light emitting cell, the second light emitting cell comprising a second light emitting layer;
a first electrode electrically connected to the first light emitting cell; and
a second electrode electrically connected to the second light emitting cell,
the first light emitting cell is electrically connected to the second light emitting cell through the first tunnel junction layer, and
the first LED element is a flip-chip type LED element in which the first electrode and the second electrode are arranged toward a surface of the first LED element opposite to a light emitting surface of the first LED element.

5. The display panel as claimed in claim 4, wherein the first light emitting layer and the second light emitting layer have matching band gap characteristics.

6. The display panel as claimed in claim 5, wherein the matching band gap characteristics of the first light emitting layer and the second light emitting layer correspond to a wavelength of red light.

7. The display panel as claimed in claim 4, wherein the first light emitting cell comprises the first light emitting layer, a first n-type semiconductor layer formed above or beneath the first light emitting layer, and a first p-type semiconductor layer formed on a surface of the first light emitting layer opposite to a surface of the first light emitting layer on which the first n-type semiconductor layer is formed,
the second light emitting cell comprises the second light emitting layer, a second n-type semiconductor layer formed above or beneath the second light emitting layer, and a second p-type semiconductor layer formed on a surface of the second light emitting layer opposite to a surface of the second light emitting layer on which the second n-type semiconductor layer is formed, and
the first n-type semiconductor layer or the first p-type semiconductor layer that is formed above the first light emitting layer, the second light emitting layer, the second n-type semiconductor layer, and the second p-type semiconductor layer transmit light emitted by the first light emitting layer and the second light emitting layer.

8. The display panel as claimed in claim 4, wherein the first LED element further comprises:
a contact hole extending through the first light emitting cell, the first tunnel junction layer, and a part of the second light emitting cell; and
an insulating layer formed on a surface of the contact hole, and
the second electrode is electrically connected to the second light emitting cell through the contact hole.

9. The display panel as claimed in claim 4, wherein the first LED element further comprises a reflective layer formed to reflect light emitted from the first light emitting layer and the second light emitting layer toward the light emitting surface of the first LED element.

10. The display panel as claimed in claim 4, wherein the first LED element further comprises:
a third light emitting cell formed between the first light emitting cell and the first tunnel junction layer, the third light emitting cell comprising a third light emitting layer; and
a second tunnel junction layer formed between the first light emitting cell and the third light emitting cell.

11. The display panel as claimed in claim 4, wherein the plurality of LED elements further comprises a second LED element, and
the second LED element comprises a single light emitting layer.

12. The display panel as claimed in claim 11, further comprising a plurality of pixels arranged in a matrix form,
wherein each of the plurality of pixels comprises a R sub-pixel, a G sub-pixel, and a B sub-pixel.

13. The display panel as claimed in claim 12, wherein at least one of the R sub-pixel, the G sub-pixel, or the B sub-pixel corresponds to the first LED element.

14. The display panel as claimed in claim 13, wherein the R sub-pixel corresponds to the first LED element, and
each of the G sub-pixel and the B sub-pixel corresponds to the second LED element.

15. The display panel as claimed in claim 13, wherein each of the R sub-pixel, the G sub-pixel, and the B sub-pixel corresponds to the first LED element.

16. The display panel as claimed in claim 13, wherein the light emitting surface of the first LED element and a light emitting surface of the second LED element are formed to have a corresponding height.

17. The display panel as claimed in claim 4, wherein each of the plurality of LED elements is a micro LED element.

18. A method of manufacturing an LED element, comprising:
sequentially stacking a first n-type semiconductor layer, a first light emitting layer, and a first p-type semiconductor layer;
stacking a tunnel junction layer on a surface of the first p-type semiconductor layer opposite to the first light emitting layer;
sequentially stacking a second n-type semiconductor layer, a second light emitting layer, and a second p-type semiconductor layer on a surface of the tunnel junction layer opposite the first p-type semiconductor layer; and
forming a first electrode and a second electrode at a location removed from a light emitting surface of the LED element, the first electrode and the second electrode being electrically connected to the first n-type semiconductor layer and the second p-type semiconductor layer, respectively.

19. The method of manufacturing the LED element as claimed in claim 18, wherein the first light emitting layer and the second light emitting layer have band gap characteristics corresponding to a wavelength of red light.

20. The method of manufacturing the LED element as claimed in claim 18, further comprising:
forming a contact hole through the first n-type semiconductor layer, the first light emitting layer, the first p-type semiconductor layer, the tunnel junction layer, the second n-type semiconductor layer, the second light emitting layer, and a part of the second p-type semiconductor layer; and
forming an insulating layer on a surface of the contact hole, and
wherein the second electrode is electrically connected to the second p-type semiconductor layer through the contact hole.
